(19) United States
(12) Patent Application Publication
(10) Pub. No.: US 2025/0322872 A1
(43) Pub. Date: Oct. 16, 2025

(54) Resistive Random-Access Memory With Reduced Disturb Current in a Shared Source Line Bit Cell Architecture

(71) Applicant: WEEBIT NANO LTD, Hod Hasharon (IL)

(72) Inventors: Julien Louche, Saint Martin Le Vinoux (FR); Maxim Vershkov, Ramat Gan (IL)

(73) Assignee: WEEBIT NANO LTD, Hod Hasharon (IL)

(21) Appl. No.: 19/169,214

(22) Filed: Apr. 3, 2025

(30) Foreign Application Priority Data
Apr. 12, 2024 (FR) FR2403832

(51) Int. Cl. G11C 13/00

(52) U.S. Cl. CPC G11C 13/0033; G11C 13/0026; G11C 13/0028

(57) ABSTRACT

A resistive RAM (MEM) having a shared source line architecture, comprises an array (ARR) of bit cells (BC, BC0, BC1, BC2, BC3), each of the bit cells comprising a ReRAM resistor (Var_{R}), the array (ARR) including: a first column of bit cells (BC0) comprising a first bit line (BL0) and one source line (SL0) and a second column of bit cells (BC1) comprising a second bit line (BL1) and the one source line (SL0), the resistive RAM being configured to, during a set operation (SET) or a reset operation (RESET) of one bit cell (BC0) of the first column, open a current path (Tr2, Tr5, Tr8, Tr11) between the one source line (SL0) and the second bit line (BL1) so as to bypass a bit cell (BC1) of the second column sharing a word line (WL) with the one bit cell (BC0) of the first column.

### CROSS-REFERENCE TO RELATED APPLICATION

The present application claims priority to French Patent Application No. FR2403832 filed on Apr. 12, 2024, the contents of which are hereby incorporated by reference in their entirety.

### FIELD OF THE INVENTION

The technical domain of the invention is that of Resistive Random Access Memory (ReRAM) or Resistive RAM, that each comprise an element whose resistive state defines a bit of information.

### BACKGROUND OF THE INVENTION

Non-volatile memory (NVM) is a kind of computer memory able to retain information even after its power source is turned off. Examples of non-volatile memory include read-only memory (ROM), erasable ROM (EPROM), flash memory, ferroelectric random-access memory (FRAM), Magnetoresistive random access memory (MRAM), phase-change memory (PCM) or resistive random access memory (ReRAM).

The latter, the ReRAM, works typically by changing the electrical resistance of a layer of a dielectric solid-state material comprised between two electrodes. Such a structure constitutes a memory bit element. The dielectric solid-state material may be for example a chalcogenide, a perovskite or an oxide of a transition metal such as hafnium oxide (HfOx). A memory is formed of an array of such memory bit elements each forming the core of one bit cell.

More specifically, during a set operation, application of a set electrical current along with an associated electrical field in a first direction between the two electrodes of a given bit cell can lead to the formation of an electrically conductive filament in an otherwise electrically resistive layer due to the formation and diffusion of pairs of oxygen ions and oxygen vacancies in the volume of the dielectric material. The bit cell is then put in a low resistance state or LRS. The higher the set current, the larger the filament and the lower the resistance of the bit cell.

Conversely, during a reset operation, a reset electrical current running between the two electrodes in a second direction, opposite to the first direction, can disrupt, or dissolve, the electrically conductive filament created during the set operation, thus increasing the electrical resistance of the bit cell. The bit cell is then put in a high resistance state or HRS.

Each of the LRS and HRS states can be associated to a bit value of a digital memory. During a read operation, a read current, lower in intensity than both the set current and the read current, is run between the two electrodes to evaluate the resistive state of the bit cell, and thus the associated bit value.

The set, reset and read operations can be applied to bit cells integrated in an array ARR of a resistive RAM-type memory MEM. FIG. 1 illustrates a basic, conventional structure of a resistive memory. Such a memory is described for example in the patent U.S. Ser. No. 11/735,260B2.

Each bit cell bit BC of the array ARR comprises one ReRAM resistor Var_{R} made of a pair of electrodes EL1 and EL2 sandwiching, for example, an oxide layer OL, and one selection transistor Sel_{Tr} having a source and a drain connected in series with the ReRAM resistor.

An array ARR of bit cells comprises columns and rows of bit cells. Each column comprises (i) a bit line BL connected to a source and a drain of the transistor Sel_{Tr} through the ReRAM resistor Var_{R} for each of the bit cells of the column and (ii) a source line SL connected to the bit line BL through the source and the drain of the transistor SelTr and the ReRAM resistor Var_{R}. Each row of bit cells comprises a word line WL connected to the gate of the selection transistor Sel_{Tr} for each of the bit cells of the row. The bit lines BL and the source lines SL are each connected to and controlled through a column multiplexer circuit SL/BL-Mux. The word lines WL are each connected to and controlled by a row driver circuit WL-Drv.

In FIG. 1(A), each intersection between a word line WL and a bit line BL corresponds to a bit cell BC. FIG. 1(C) illustrates two adjacent bit cells BC1 and BC2 belonging to a same row and thus connected to a same word line WL.

The table Tab1 indicates voltages typically employed for the set, reset and read operations of a resistive memory realized by means of a 130 nm semiconductor fabrication process.

TABLE 1

| Operation | Bit line | Source line | Word line |
|---|---|---|---|
| Set | High V - 2 V | Gnd | High V - 2 V |
| Reset | Gnd | High V - 2 V | High V - 2 V |
| Read | Low V - 0.2 V | Gnd | Nominal V - 1.5 V |

In the structure illustrated by FIG. 1, the two bit cells BC1 and BC2 are connected to a respective one of two bit lines BL1 and BL2 and to a respective one of two source lines SL1 and SL2.

An important parameter in the design of a memory device is the area occupied by a single bit cell: the smaller this area, the higher the memory density and the lower the cost and the size of a memory of a given capacity.

One solution to increase the memory density for a ReRAM memory is illustrated by FIG. 2. The principle is for two adjacent bit cells of any given row to share a unique source line. This way, the number of source lines can be halved, and it is possible to reduce the overall area occupied by the memory, all other design constraints being equal.

FIG. 2(A) illustrates an overall view of the memory MEM of FIG. 1 to which the principle of source line sharing has been applied. FIG. 2(B) illustrates a group BC0/1 of two bit cells BC0 and BC1 that now share a same source line SL0 and that are each connected to a respective bit line, the bit lines BL0 and BL1, all other descriptions concerning the structures of FIG. 1 applying to FIG. 2 as well. Such a structure is mentioned in the patent EP1424697B1.

In such a configuration, two adjacent bit cells sharing a same source line are susceptible to influence one another. This is all the more true in view of the stochastic nature of the filaments formed during the set operations of the bit cells. Otherwise stated, the characteristics of the bit cells spread over ranges. In this context, FIG. 16 illustrates the resistances of a collection of bit cells of a same array.

FIGS. 16(A) and (B) illustrates the probability Pr of the resistance values R(Ω) of a bit cell in an ideal case and in a more realistic case, respectively. In the ideal case, only two values are possible, the resistance of the Low Resistance State LRS and the resistance of the High Resistance State HRS. In this ideal model, only these two states are accessible to the bit cell, and each one has a unique, well defined, resistance value. However, in practice, the resistance values spread over ranges that can each be described as a probability density having the shape of a peak centered on a given value (V_{0_LRS} and V_{0_HRS} for the two states LRS and HRS, respectively) and presenting a standard deviation σ (similar repartitions for LRS and HRS in this example, for the sake of keeping the explanation simple), as illustrated by FIG. 16(B).

We see that the two states LRS and HRS can in fact be close to one another, the distributions of these two states can even overlap. In some circumstances, it may become difficult to ascertain whether a given first bit cell is in the LRS state or HRS state. This is especially true for the shared source line architecture, considering that this first bit cell may be influenced by a second one sharing a common source line with the first one. Indeed, the state of the first bit cell may progressively drift apart from the one that has been written (set or reset) initially due to the impact of the current used to set or reset the second one.

Therefore, there is a need of improving ReRAM memories employing a shared source line architecture.

### OBJECT OF THE INVENTION

In the context described above, the inventors propose to limit the impact of the set and reset operations of a first bit cell on a second bit cell that shares a source line with the first bit cell.

### SUMMARY OF THE INVENTION

To this effect, a first aspect of the invention relates to a resistive RAM having a shared source line architecture, comprising an array of bit cells, a multiplexer circuit and a driver circuit, each of the bit cells comprising a ReRAM resistor and a selection transistor connected to the ReRAM resistor, the array including: a first column of bit cells comprising a first bit line and one source line, each connected to the multiplexer circuit, the one source line being connected to the first bit line in each of the bit cells of the first column through the respective ReRAM resistors and selection transistors; a second column of bit cells comprising a second bit line and the one source line, each connected to the multiplexer circuit, the one source line being connected to the second bit line in each of the bit cells of the second column through the respective ReRAM resistors and selection transistors, a given row of bit cells comprising a word line connecting gates of the selection transistors of a given one of the bit cell of the first column and a given one of the bit cells of the second column to the driver circuit; a first additional transistor configured to connect the first bit line to a node connected to the one source line, a gate of the first additional transistor being connected to the second bit line; a second additional transistor configured to connect the node connected to the second bit line, a gate of the second additional transistor being connected to the first bit line; and a third additional transistor configured to connect the node to the one source line.

In a resistive RAM according to the invention, configured to open a current path between the common source line shared by a first and a second columns of bit cells, and the bit line of a bit cell of the second column when a bit cell of the first column is to be set or reset, disturb currents susceptible to flow into the bit cell of the second column are reduced in intensity and in duration, so that the bit error rate and the retention degradation of the resistive RAM are advantageously reduced.

According to further non limitative features of the first aspect of the invention, either taken alone or in any technically feasible combination:
the resistive RAM can be configured to, during a set operation or a reset operation of the given one of the bit cells of the first column, open a current path between the one source line and the second bit line so as to bypass the given bit cell of the second column.
the resistive RAM can be configured to, during a set operation or a reset operation of the given one of the bit cells of the first column, turn off the first transistor and turn on the second transistor;
the resistive RAM can be configured to: when the first transistor, the second transistor and the third transistor are n-type transistors, turn on the third transistor during a set operation of the given one of the bit cells of the first column, and turn off the third transistor during a reset operation of the given one of the bit cells of the first column, and when the first transistor, the second transistor and the third transistor are p-type transistors, turn on the third transistor during a reset operation of the given one of the bit cells of the first column, and turn off the third transistor during a set operation of the given one of the bit cells of the first column;
wherein the array can be interposed between the multiplexer circuit and each of the first additional transistor and the second additional transistor, wherein the second additional transistor can constitute a part of the current path between the one source line and the second bit line;
the first additional transistor and the second additional transistor can be n-type transistors, and the resistive RAM can be configured to turn on the second additional transistor to thereby open the current path between the one source line and the second bit line during the set operation;
a source or a drain of the first additional transistor can be connected to a source or a drain of the second additional transistor at a the node, the third additional transistor being an n-type transistor, the resistive RAM can be configured to turn on the third additional transistor during a set operation and to turn off the third additional transistor during a reset operation;
the first additional transistor and the second additional transistor are p-type transistors, and the resistive RAM is configured to turn on the second additional transistor to thereby open the current path between the one source line and the second bit line during the reset operation;
a source or a drain of the first additional transistor can be connected to a source or a drain of the second additional transistor at the node, the third additional transistor being a p-type transistor, the resistive RAM being configured to turn on the third additional transistor during a reset operation and to turn off the third additional transistor during a set operation;
each of the first additional transistor and the second additional transistor can be interposed between the array and the multiplexer circuit, the second additional transistor can constitute a part of the current path between the one source line and the second bit line;
the first additional transistor and the second additional transistor can be n-type transistors, and the resistive RAM can be configured to turn on the second additional transistor to thereby open the current path between the one source line and the second bit line during the set operation;
a source or a drain of the additional first additional transistor can be connected to a source or a drain of the second additional transistor at the node, the third additional transistor being an n-type transistor, the resistive RAM can be configured to turn on the third additional transistor during a set operation and to turn off the third additional transistor during a reset operation;
the first additional transistor and the second additional transistor can be p-type transistors, and the resistive RAM can be configured to turn on the second additional transistor to thereby open the current path between the one source line and the second bit line during the reset operation;
a source or a drain of the additional first additional transistor can be connected to a source or a drain of the second additional transistor at a second node, the third additional transistor being a p-type transistor, the resistive RAM can be configured to turn on the third additional transistor during a reset operation and to turn off the third additional transistor during a set operation;
the resistive RAM can be further configured to, for the reset operation of the given one of the bit cells of the first column, charging the one source line and the second bit line of the given one of the bit cells of the second column prior to charging the word line of the given row.

The invention extends to an embedded system including the resistive RAM according the first aspect of the invention, connected to a microprocessor.

### BRIEF DESCRIPTION OF DRAWINGS

Many other features and advantages of the present invention will become apparent from reading the following detailed description, when considered in conjunction with the accompanying drawings, in which:

FIG. 1 illustrates a known, generic architecture of a resistive RAM;

FIG. 2 illustrates a resistive RAM employing an architecture with a source line shared between two columns of an array of bit cells;

FIG. 3 illustrates a configuration of the resistive RAM of FIG. 2;

FIG. 4 illustrates the apparition of a disturb current during a set operation in the memory of FIG. 3;

FIG. 5 illustrates a disturb current appearing during a set operation on a bit cell of the memory of FIG. 4;

FIG. 6 illustrates a specific implementation of the first variant of FIG. 7;

FIG. 7 illustrates a first variant to reduce a disturb current of a set operation;

FIG. 8 illustrates a second variant to reduce a disturb current of a set operation;

FIG. 9 illustrates a specific implementation of the second variant of FIG. 8;

FIG. 10 illustrates the apparition of a disturb current during a reset operation in the memory of FIG. 3;

FIG. 11 illustrates a disturb current appearing during a reset operation on a bit cell of the memory of FIG. 10;

FIG. 12 illustrates a first variant to reduce a disturb current of a reset operation;

FIG. 13 illustrates a second variant to reduce a disturb current of a reset operation;

FIG. 14 illustrates a specific implementation of the first variant of FIG. 12;

FIG. 15 illustrates a specific implementation of the second variant of FIG. 13;

FIG. 16 illustrates the repartition of the resistivities of bit cells of a resistive memory;

FIG. 17 illustrates representations of transistors;

FIG. 18 represents chronograms of two different driving methods of a bit cell; and

FIG. 19 illustrates an embedded systems incorporating a resistive RAM.

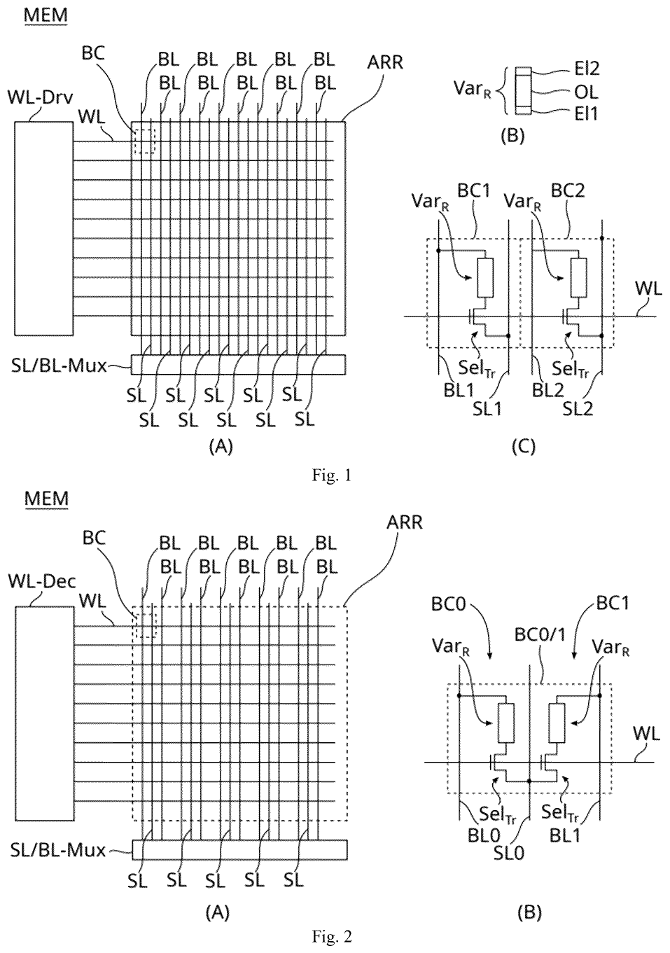

### DETAILED DESCRIPTION OF A FIRST EMBODIMENT OF THE INVENTION

The behavior of the resistive memory MEM of FIG. 2, that has a shared source line structure during a set operation SET, is explained in detail below.

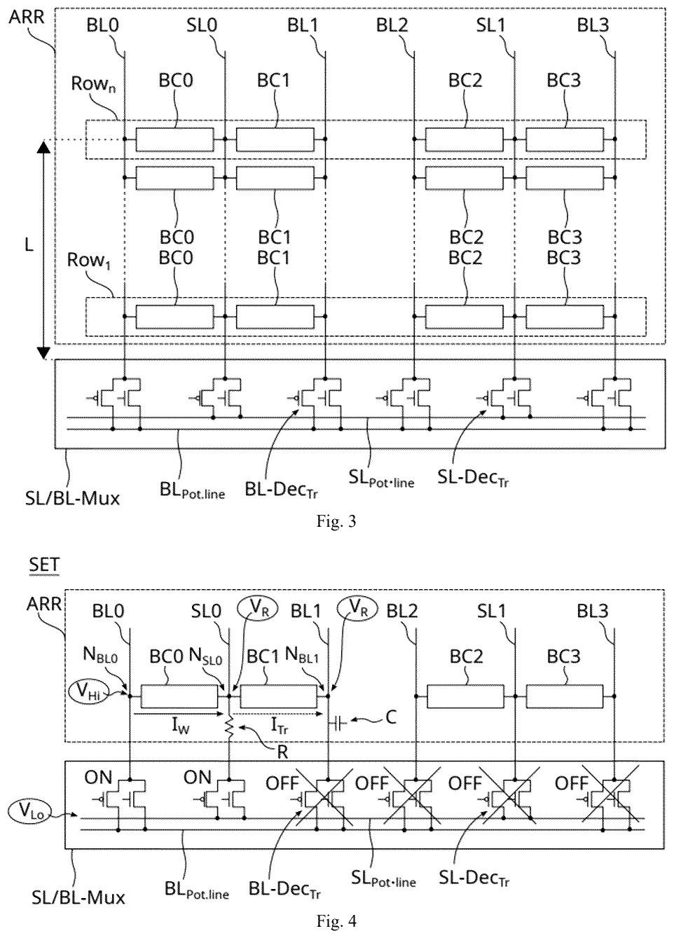

FIG. 3 represents a schematic implementation of the memory illustrated by FIG. 2. Only elements pertinent to the following explanations are represented in FIG. 3, which includes the array ARR, four columns of bit cells comprising respective bit cells BC0, BC1, BC2 and BC3, and the multiplexer circuit SL/BL-Mux to which the source lines and the bit lines are connected. The bit cells BC0 connected to the bit line BL0 share a common source line SL0 with the bit cells BC1 connected to the bit line BL1. Similarly, the bit cells BC2 connected to the bit line BL2 share a common source line SL1 with the bit cells BC3 connected to the bit line BL3. It is to be understood that the array ARR of bit cells is made of such pairs of columns of bit cells, each column of a given pair sharing a common source line.

In this example, the memory comprises n rows of bit cells numbered from 1 to n, the closest row from the multiplexer circuit being the 1^{st} row Row₁ and the farthest row from the multiplexer circuit being the n^{th} row Rowₙ.

FIG. 3 shows that the bit lines and the source lines extend over a length L from multiplexer circuit SL/BL-Mux to the n^{th} row Rowₙ of bit cells. In effect, these lines thus present a significant electrical resistance R between the multiplexer circuit and the bit cells of the n^{th} row Rowₙ.

FIG. 4 is a simplified version of FIG. 3, where only the n^{th} row is represented, as well as the electrical resistor R formed by the source line SL0. The first bit cell BC0 is connected to the bit line BL0 at a node N_{BL0} and to the source line SL0 at a node N_{SL0}, and the second bit cell BC1 is connected to the source line SL0 at the node N_{SL0} and to the bit line BL1 at a node N_{BL1}. The bit lines are connected to a bit line potential line BL_{Pot.Line} via respective transistors BL-Dec_{Tr} in the multiplexer circuit SL/BL-Mux. Similarly, the source lines are connected to a source line potential line SL_{Pot.Line} via respective transistors SL-Dec_{Tr} in the multiplexer circuit SL/BL-Mux.

FIG. 4 illustrates more specifically the electrical situation of the array during a set operation SET of the bit cell BC0 of the first row.

During the set operation of the bit line BC0, a high voltage (not shown) is applied to the word line WL connected to the selection transistor Sel_{Tr} of the bit cell BC0 so as to turn the transistor on, a high voltage V_{Hi} is applied to the node N_{BL0} by means of the potential line BL_{Pot.Line} and the respective transistors BL-Dec_{Tr} being turned on, a low voltage V_{Lo} is applied to the node N_{SL0} by means of the potential line SL_{Pot.Line} and the respective transistors SL-Dec_{Tr} being turned on, and the other source and bit lines, BL1, BL2, SL1 and BL3 in FIG. 4, are floating, their connections to potential lines BL_{Pot.Line} and SL_{Pot.Line} being cut off due to their respective transistors BL-Dec_{Tr} SL-Dec_{Tr} being turned off. The node NBL1, situated on the bit line BL1, is also floating.

A direct writing current I_{w} runs from the bit line potential line BL_{Pot.Line} to the source line potential line SL_{Pot.line} through the bit cell BC0, and thus through the ReRAM resistor of the bit cell BC0, so as to form a filament in the dielectric layer OL and set the state of the bit cell BC0 into the low resistance state LRS. The current I_{w} also runs through the bit line BL0 and the source line SL0.

In this situation, a potential V_{R} appears at the node N_{SL0} due to a voltage drop through the resistance R. Consequently, and since the bit line BL1 has a non-negligible capacitance, and the select transistor of the bit cell BC1 is on because it shares the same word line WL with the bit cell BC0, a transient current I_{Tr} runs through the bit cell BC1 until the capacitor C associated to the bit line BL1 is loaded and the potential V_{R} appears at the node N_{BL1}.

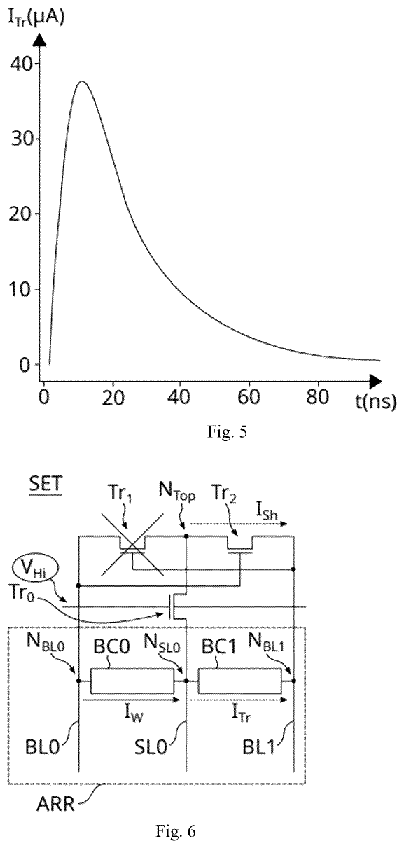

Typical values for the V_{Hi}, V_{Lo} and the V_{R} potentials are 2.4V, 0.1V and 0.8V. Of course, depending on the logic circuits employed or RC parasitic components between the source line potential and the ground, other values are possible, lower or higher. With the values mentioned above, a typical profile of the current I_{Tr} is represented in FIG. 5. After an initial peak, it quickly decreases to 0 as the capacitor C is loaded and the potential of the node N_{BL1} becomes equal to the potential of the node N_{SL0}.

Such a transient, unwanted current I_{Tr} is also called “disturb current”. The reason is that this current can disturb, meaning change in an uncontrolled manner, the state of the bit cell BC1 of the second column. Indeed, although the transient current is short and of small intensity compared to the writing current I_{w}, the effect on the state of the bit cell BC1 is cumulative.

The explanation above has taken the n^{th} row of bit cell as an example of the worst-case situation with the highest resistance value for the resistor R, but it should be understood that the disturb current appears to the other rows as well, even though the severity of the influence of the disturb current is dependent on their locations in the array, especially their distance to the multiplexer circuit SL/LB-Mux.

At the scale of the entire array ARR of a typical memory and taking in addition into account the variability of the characteristics of the ReRAM resistors VarR, this disturb current becomes a real issue that must be addressed.

### Set Disturb Current Reduction—Variant 1

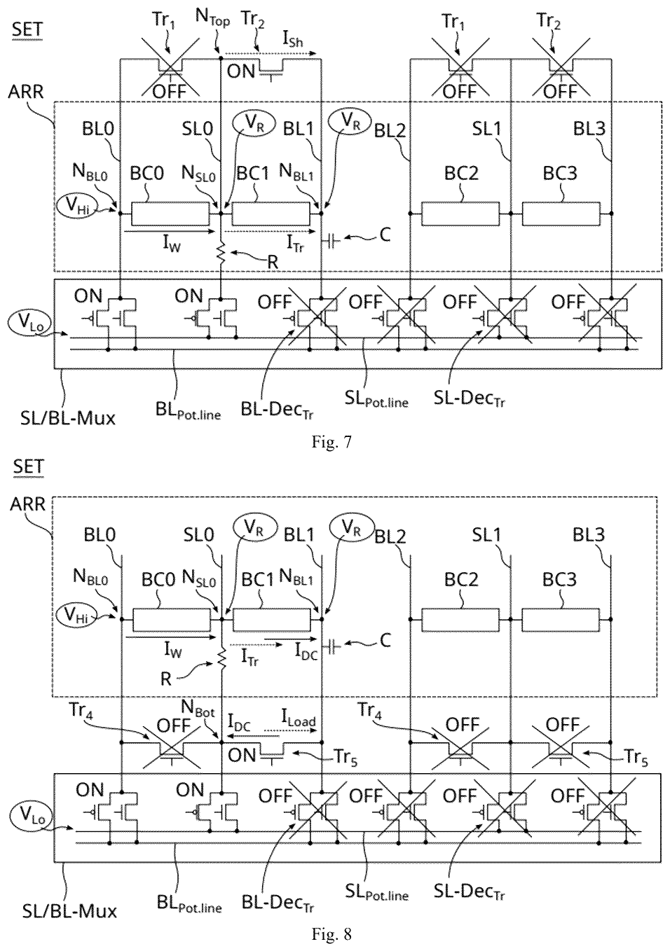

FIG. 7 illustrates a first solution to reduce the disturb transient current I_{Tr} occurring during a set operation of a bit cell BC0 of the first column.

This solution consists in adding transistors to the memory illustrated by FIGS. 3 and 4: a transistor Tr₁ connecting the bit line BL0 to a node N_{Top} connected to the source line SL0, and a transistor Tr₂ connecting the node N_{Top} to the bit line BL1. Otherwise stated, a source or a drain of the transistor Tr₁ is connected to a source or a drain of the transistor Tr₂ at the node N_{Top}.

The array ARR of bit cells is interposed between the multiplexer circuit SL/BL-Mux and each of the transistors Tr₁ and Tr₂, so that these transistors are on the side of the array opposite to the multiplexer circuit SL/BL-Mux and close to the first row Row₁ of bit cells.

This first solution is described as “Top-assist”, as the circuit elements used to reduce the disturb current are on a top side of the array in a conventional representation as the one of FIG. 7.

The memory MEM integrating the transistors Tr₁ and Tr₂ is configured so that, during a set operation of bit cell BC0, the transistor Tr₁ is turned off and the transistor Tr₂ is turned on.

Then, not only the transient current I_{Tr} but also a shunt current I_{Sh} load the capacitor C formed by the bit line BL1 until the potential V_{R} is attained at the node N_{BL1}, so that the transient current I_{Tr} is reduced in intensity and in duration. Otherwise stated, the transistor Tr₂ allows to, at least partly, bypass the bit cell BC1 to load the capacitor C, so that the disturb current indicated as the transient current I_{Tr} is reduced.

Since the transient current is reduced, its influence on the bit cell BC1 is advantageously reduced, and the reliability of the memory in terms of bit error rate and retention degradation is advantageously enhanced.

The transistors Tr₁ and Tr₂ may be controlled in conventional ways, for example by means of a decoder or a multiplexer performing bit cell address decoding, similarly to the way the bit lines and the source lines are controlled. This may be done for example by connecting the gates of the transistors Tr₁ and Tr₂ to the multiplexer SL/BL-Mux. However, considering that the transistors Tr₁ and Tr₂ are on the side of the array ARR opposite to the multiplexer, this solution requires a large area in the memory. On the other hand, FIG. 6 illustrates an implementation that is advantageous in that it requires only a small area.

As illustrated by FIG. 6, the gate of the transistor Tr₁ is connected to the bit line BL1, and, conversely, the gate of the transistor Tr₂ is connected to the bit line BL0. In this way, when the bit cell BC0 is selected for a set operation, the transistor Tr₂ is turned on, because BL0 voltage is greater than the sum of BL1 voltage and the threshold voltage of the transistor Tr₂, and the transistor Tr₁ is turned off, because BL1 is always lower or equal to SL0 so that the gate-source voltage of Tr₁ is less than the threshold voltage of Tr₁, as intended.

In addition, a transistor Tr₀ is connected between the node N_{Top} and the source line SL0. The memory MEM is configured to turn on the transistor Tr₀ by applying a high voltage V_{Hi} to its gate during a set operation SET, in order to allow the memory to function as explained for the memory illustrated by FIG. 7. Conversely, during a reset operation RESET, a low voltage is applied to this third transistor, so as to turn it off in order to avoid shorting the selected cell BC0 via the transistor Tr₁.

The description above applies to the columns of bit cells BC0 and BC1 that are concerned with the set operation of a bit cell BC0, but it is to be understood that each pair of columns of bit cells sharing a same source line have the transistors Tr₁, Tr₂ and, when the implementation of FIG. 6 is employed, the transistor Tr₀. When a column is not concerned with the bit cell to be set, the transistors Tr₁, Tr₂ and optional transistor Tr₀ stay turned off, as illustrated with the columns of bit cells BC2 and BC3 in FIG. 7.

### Set Disturb Current Reduction—Variant 2

FIG. 8 illustrates a second solution to reduce the disturb transient current I_{Tr} occurring during a set operation of a bit cell BC0 of the first column.

This solution consists adding new transistors to the memory illustrated by FIGS. 3 and 4: a transistor Tr₄ connecting the bit line BL0 to a node N_{Bot} of the source line SL0, and a transistor Tr₅ connecting the node N_{Bot} to the bit line BL1. Otherwise stated, a source or a drain of the transistor Tr₄ is connected to a source or a drain of the transistor Tr₅ at the node N_{Bot}.

The transistors Tr₄ and Tr₅ are interposed between the multiplexer circuit SL/BL-Mux and the array ARR of bit cells, so that these transistors are on the side of the array close to the multiplexer circuit SL/BL-Mux and close to the 1^{st} row Row₁ of bit cells.

This second solution is described as “Bottom-assist”, as the circuit elements used to reduce the disturb current are on a bottom side of the array in a conventional representation as the one of FIG. 8.

The memory MEM integrating the transistors Tr₄ and Tr₅ is configured so that, during a set operation, the transistor Tr₄ is turned off and the transistor Tr₅ is turned on.

Then, not only the disturb transient current I_{Tr} but also a shunt current I_{Sh} load the capacitor formed by the bit line BL1 until the potential V_{R} is attained at the node N_{BL1}, so that the disturb transient current I_{Tr} is reduced in intensity and in duration. Otherwise stated, the transistor Tr₅ allows to, at least partly, bypass the bit cell BC1 to load the capacitor C, so that the disturb current indicated as the transient current I_{Tr} is reduced.

Since the transient current is reduced, its influence on the bit cell BC1 is advantageously reduced, and the reliability of the memory in terms of bit error rate and retention degradation is advantageously enhanced.

However, it should be noted that, in this second variant, a direct current I_{DC} may run through the unselected bit cell BC1 because a parallel path from the source line SL0 to the line at the V_{Lo} potential via the transistor Tr₅ is created. The direct current I_{DC} depends on the resistance of the bit line BL1. Practically speaking, this current is relatively weak and has no significant impact.

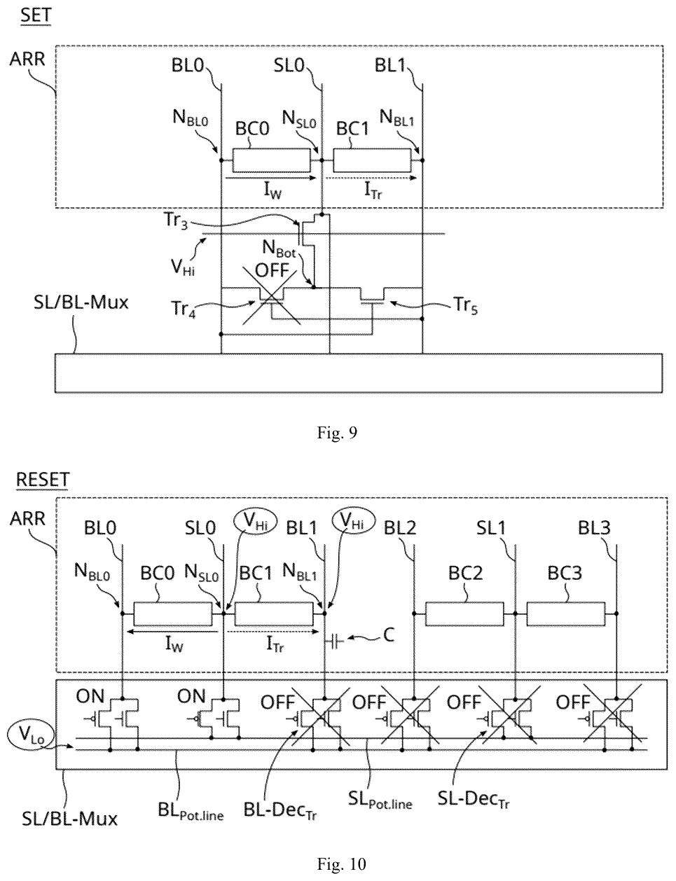

The transistors Tr₄ and Tr₅ may be controlled in conventional ways, for example by means of a decoder or a multiplexer, similarly to the way the bit lines and the source lines are controlled. Since the transistors Tr₄ and Tr₅ are, in this second variant, in close proximity to the multiplexer SL/BL-Mux, it may be advantageous to control their respective gates by means of this multiplexer circuit, which would not require a large area in the memory. Still, FIG. 9 illustrates an alternative implementation.

As illustrated by FIG. 9, the source line SL0 is still directly connected to the multiplexer SL/BL-Mux, the gate of the transistor Tr₄ is connected to the bit line BL1, and, conversely, the gate of the transistor Tr₅ is connected to the bit line BL0. In this way, when the bit cell BC0 is connected for a set operation, the transistor Tr₅ is turned on and the transistor Tr₄ is turned off, as intended.

In addition, a transistor Tr₃ connects the node N_{Bot} to the source line SL0. The memory MEM is configured to turn on the transistor Tr₃ by applying a high voltage V_{Hi} to its gate during a set operation SET, in order to allow the memory to function as explained for the memory illustrated by FIG. 8. Conversely, during a reset operation RESET, a low voltage is applied to this third transistor, so as to turn it off in order to avoid shorting the selected cell BL1 via the transistor Tr₄.

The description above applies to the columns of bit cells BC0 and BC1 that are concerned with the set operation of a bit cell BC0, but it is to be understood that each pair of columns of bit cells sharing a same source line have the transistors Tr₄, Tr₅ and, when the implementation of FIG. 9 is employed, the transistor Tr₃. When a column is not concerned with the bit cell to be set, the transistors Tr₄, Tr₅ and optional transistor Tr₃ may stay turned off, as illustrated with the columns of bit cells BC2 and BC3 in FIG. 8. However, regardless of the states of these transistors, connection to BL_{Pot.Line} and SL_{Pot.Line} are closed and the bit lines and the source line are floating, without potentially harmful currents running.

The transistors Sel_{Tr} and Tr₀ to Tr₅ are preferably n-type transistors.

### DETAILED DESCRIPTION OF A SECOND EMBODIMENT OF THE INVENTION

The inventors analyzed the behavior of the resistive memory MEM of FIG. 2, that has a shared source line structure during a reset operation RESET.

FIG. 10 is similar to FIG. 4, except that it illustrates more specifically the electrical situation of the array during a reset operation RESET of the bit cell BC0 of the first row.

During the reset operation of the bit cell BC0, a high voltage (not shown) is applied to the word line WL connected to the select transistors of the first row of bit cells, including the select transistor Sel_{Tr} of the bit cell BC0 so as to turn the transistor on, a high voltage V_{Hi} is applied to the node N_{SL0} by means of the potential line SL_{Pot.Line} and the respective transistors SL-Dec_{Tr} being turned on, a low voltage V_{Lo} is applied to the node N_{BL0} by means of the potential line BL_{Pot.Line} and the respective transistors BL-Dec_{Tr} being turned on, and the other source lines and bit lines, BL1, BL2, SL1 and BL3 in FIG. 4, are floating, their connections to potential lines BL_{Pot.Line} and SL_{Pot.Line} being cut off due to their respective transistors BL-Dec_{Tr}SL-Dec_{Tr} being turned off. The node NBL1, situated on the bit line BL1, is also floating.

Preferably, prior to being made floating, the other source lines and bit lines, BL1, BL2, SL1 and BL3 are discharged by being connected to a low potential line such as a ground potential in order to avoid any parasitic current when the word line is open.

A direct writing current I_{w} runs from the source line SL0 to the line BL_{Pot.line} through the bit cell BC0, and thus through the ReRAM resistor of the bit cell BC0, so as to dissolve a filament formed during a set operation in the dielectric layer OL and reset the state of the bit cell BC0 into the high resistance state HRS.

In this situation, a transient current I_{Tr} runs through the bit cell BC1 until the capacitor C is loaded and the potential V_{Hi} appears at the node N_{BL1}.

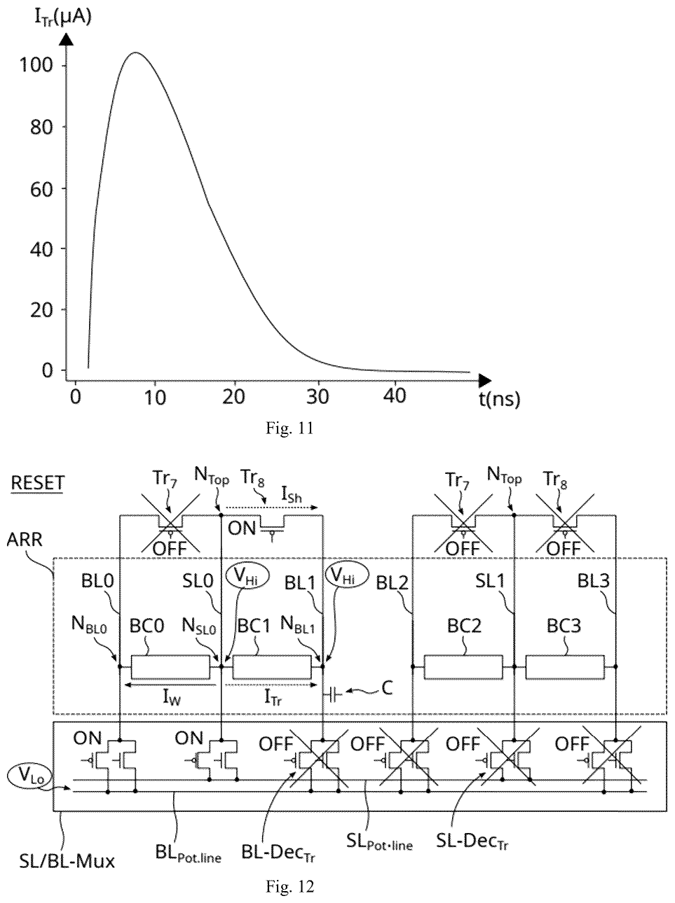

Typical value for the V_{Hi} potential and the potential at the N_{BL0} node are 2.4V and 0.1V, respectively. With such values, a typical profile of the current I_{Tr} is represented in FIG. 11. After an initial peak, it quickly decreases to 0 as the capacitance C is loaded and the potential of the node N_{BL1} becomes equal to the potential of the node N_{SL0}.

Compared to the transient current generated by a set operation and illustrated by FIG. 5, the transient current generated by a reset operation attains a higher intensity. This is because the potential of the node N_{SL0} that generates the transient current I_{Tr} is higher in the reset operation, equal to the high voltage applied V_{Hi}, while it is only equal to the drop voltage V_{R}, lower than V_{Hi}, of the set operation.

Also, the closest the row of a bit cell is from the multiplexer, the greater the influence of the transient current. This is because, considering the linear electrical resistance of the line SL0, the closer a row is from the multiplexer, the higher is the voltage on the line SL0 and the higher is the intensity of the disturb transient current generated in response to this voltage.

As in the case of a set operation described above, the transient, unwanted current I_{Tr} is a disturb current that could change in a uncontrolled manner the state of the bit cell BC1 of the second column. Indeed, although the transient current is short and of small intensity compared to the writing current I_{w}, the effect on the state of the bit cell BC1 is cumulative.

At the scale of the entire array ARR of a typical memory and taking in addition into account the variability of the characteristics of the ReRAM resistors VarR, this disturb current becomes a real issue that must be addressed.

### Reset Disturb Current Reduction—Variant 1

FIG. 12 illustrates a first solution to reduce the disturb, transient current I_{Tr} occurring during a reset operation of a bit cell BC0 of the first column.

This solution consists adding new transistors to the memory illustrated by FIGS. 3 and 4: a transistor Tr₇ connecting the bit line BL0 to the node N_{Top} that is itself connected to the source line SL0, and a transistor Tr₈ connecting the node N_{Top} to the bit line BL1. Otherwise stated, a source or a drain of the transistor Tr₇ is connected to a source or a drain of the transistor Tr₈ at the node N_{Top}.

The array ARR of bit cells is interposed between the multiplexer circuit SL/BL-Mux and each of the transistors Tr₇ and Tr₈, so that these transistors are on the side of the array opposite to the multiplexer circuit SL/BL-Mux and close to the first row Row₁ of bit cells.

This first solution is described as “Top-assist”, as the circuit elements used to reduce the disturb current are on a top side of the array in a conventional representation as the one of FIG. 12.

The memory MEM integrating the transistors Tr₇ and Tr₈ is configured so that, during a reset operation, the transistor Tr₇ is turned off and the transistor Tr₈ is turned on.

Then, not only the transient current I_{Tr} but also a shunt current I_{Sh} load the capacitor C formed by the bit line BL1 until the potential V_{Hi} is attained at the node N_{BL1}, so that the transient current I_{Tr} is reduced in intensity and in duration. Otherwise stated, the transistor Tr₈ allows to, at least partly, bypass the bit cell BC1 to load the capacitor C, so that the disturb current indicated as the transient current I_{Tr} is reduced.

Since the transient current is reduced, its influence on the bit cell BC1 is advantageously reduced, and the reliability of the memory in terms of bit error rate and retention degradation is advantageously enhanced.

The transistors Tr₇ and Tr₈ may be controlled in conventional ways, for example by means of a decoder or a multiplexer performing bit cell address decoding, similarly to the way the bit lines and the source lines are controlled. This may be done, for example by connecting the gates of the transistors Tr₇ and Tr₈ to the multiplexer circuit SL/BL-Mux. However, considering that the transistors Tr₇ and Tr₈ are on the side of the array opposite to the multiplexer circuit, this solution requires a large area in the memory. On the other hand, FIG. 14 illustrates an implementation that is advantageous in that it requires only a small area.

As illustrated by FIG. 14, the gate of the transistor Tr₇ is connected to the bit line BL1, and, conversely, the gate of the transistor Tr₈ is connected to the bit line BL0. In this way, when the bit cell BC0 is selected for a reset operation, the transistor Tr₈ is turned on and the transistor Tr₇ is turned off, as intended.

In addition, a transistor Tr₆ is connected between the node N_{Top} and the source line SL0. The memory MEM is configured to turn on the transistor Tr₀ by applying a low voltage V_{Lo} to its gate during a reset operation RESET, in order to allow the memory to function as explained for the memory illustrated by FIG. 12. Conversely, during a set operation SET, a high voltage is applied to this third transistor, so as to turn it off in order to avoid shorting the selected cell BL1 via the transistor Tr₇.

### Reset Disturb Current Reduction—Variant 2

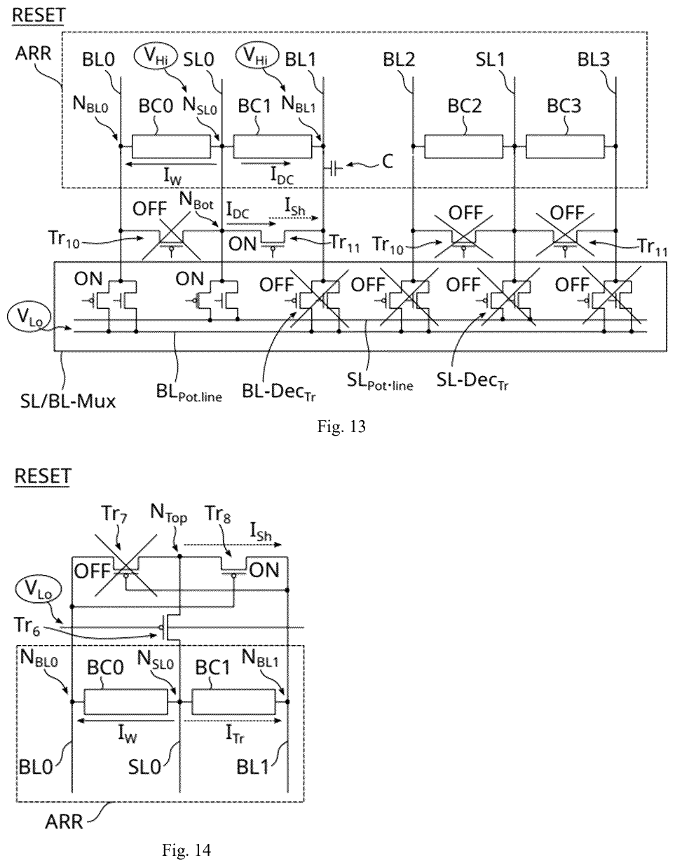

FIG. 13 illustrates a second solution to reduce the disturb, transient current I_{Tr} occurring during a reset operation of a bit cell BC0 of the first column.

This solution consists in adding transistors to the memory illustrated by FIGS. 3 and 4: a transistor Tr₁₀ connecting the bit line BL0 to the node N_{Bot} of the source line SL0, and a transistor Tr₁₁ connecting the node N_{Bot} to the bit line BL1. Otherwise stated, a source or a drain of the transistor Tr₁₀ is connected to a source or a drain of the transistor Tr₁₁ at the node N_{Bot}.

The transistors Tr₁₀ and Tr₁₁ are interposed between the multiplexer circuit SL/BL-Mux and the array ARR of bit cells, so that these transistors are on the side of the array close to the multiplexer circuit SL/BL-Mux and close to the 1ₛₜ row Row₁ of bit cells.

This second solution is described as “Bottom-assist”, as the circuit elements used to reduce the disturb current are on a bottom side of the array in a conventional representation as the one of FIG. 13.

The memory MEM integrating the transistors Tr₁₀ and Tr₁₁ is configured so that, during a reset operation, the transistor Tr₁₀ is turned off and the transistor Tr₁₁ is turned on.

Then, not only the transient current I_{Tr} but also a shunt current I_{Sh} load the capacitor formed by the bit line BL1 until the potential V_{Hi} is attained at the node N_{BL1}, so that the transient current I_{Tr} is reduced in intensity and in duration. Otherwise stated, the transistor Tr₁₁ allows to, at least partly, bypass the bit cell BC1 to load the capacitor C, so that the disturb current indicated as the transient current I_{Tr} is reduced.

Since the transient current is reduced, its influence on the bit cell BC1 is advantageously reduced, and the reliability of the memory in terms of bit error rate and retention degradation is advantageously enhanced.

However, it should be noted that, in this variant, a direct current I_{DC} may run through the unselected bit cell BC1 because a parallel path from the source line SL0 to the ground via the transistor Tr₁₁ is created. Still, this current is relatively weak and has a low impact.

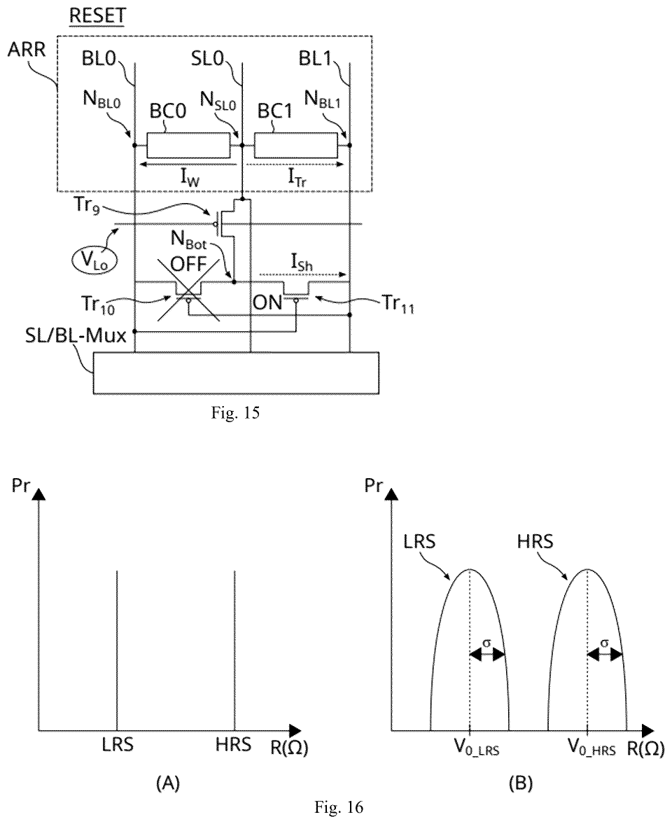

The transistors Tr₁₀ and Tr₁₁ may be controlled in conventional ways, for example by means of a decoder or a multiplexer, similarly to the way the bit lines and the source lines are controlled. Since the transistors Tr₁₀ and Tr₁₁ are, in this second variant, in close proximity to the multiplexer circuit SL/BL-Mux, it may be advantageous to control their respective gates by means of this multiplexer circuit, which would not require a large area in the memory. Still, FIG. 15 illustrates an alternative implementation.

As illustrated by FIG. 15, the source line SL0 is still directly connected to the multiplexer circuit SL/BL-Mux, the gate of the transistor Tr₁₀ is connected to the bit line BL1, and, conversely, the gate of the transistor Tr₁₁ is connected to the bit line BL0. In this way, when the bit cell BC0 is selected for a reset operation, the transistor Tr₁₀ is turned off and the transistor Tr₁₁ is turned on, as intended.

In addition, a transistor Tr₉ connects the node N_{Bot} to the source line SL0. The memory MEM is configured to turn on the transistor Tr₉ by applying a low voltage V_{Lo} to its gate during a reset operation RESET, in order to allow the memory to function as explained for the memory illustrated by FIG. 13. Conversely, during a set operation SET, a high voltage is applied to this third transistor, so as to turn it off in order to avoid shorting the selected cell BL1 via the transistor Tr₁₀.

The transistors Tr₆ to Tr₁₁ are preferably p-type transistors.

### Reset Disturb Current Reduction—Variant 3

As illustrated by FIG. 10, the transient current I_{Tr} running through the non-selected bit cell BC1 is generated by the source line SL0 having a potential higher than a potential of the bit line BL1 when the word line WL is charged at a high voltage to turn on the select transistor Sel_{Tr} of the selected bit cell BC0 to be reset, which also turns on the select transistor Sel_{Tr} of the non-selected bit cell BC1. As conventionally understood, charging a line should be construed as applying to this line a potential that is higher than the current potential of this line, for example via a connection to a line of a fixed potential via a control circuit, such as a multiplexer circuit or a driver circuit.

An additional method to reduce this transient current I_{Tr} in the non-selected bit cell BC1 is explained below. It is understood that, in this context, the selected bit cell is the bit cell to be set or reset and the non-selected bit cell is a bit cell of a same row and sharing a source line with the selected bit cell, but that is not intended to be set or reset.

The principle of this method is to delay the charging of the word line WL compared to the charging of the source line or in other words initiating the charging of the source line SL0 prior to initiating the charging of the word line WL. In addition, a charging of the bit line BL1 is also initiated prior to the initiation of the WL charging. These operations are realized in such a manner as to, when the charging of the word line WL is initialized, the voltage between SL0 and BL1 is low or null, so that only a weak or no transient current I_{Tr} runs through the bit cell BC1.

According to this principle charging of the source line and the bit line of a non-selected bit cell that shares this source line with a selected bit cell of a same row is preferably done typically 50 ns, for example between 1 and 100 ns, preferably between 20 and 80 ns, prior to initiating the charging of their common word line. This timing should be chosen so as to not having a too high impact onto the programming time, that is typically about 500 ns.

The charging voltage of the bit line of the non-selected bit cell is preferably about 80%, for example between 60% and 90% of the programming voltage of the resistive RAM, so that the voltage of the bit line is close to V_{Hi} when the word line is charged.

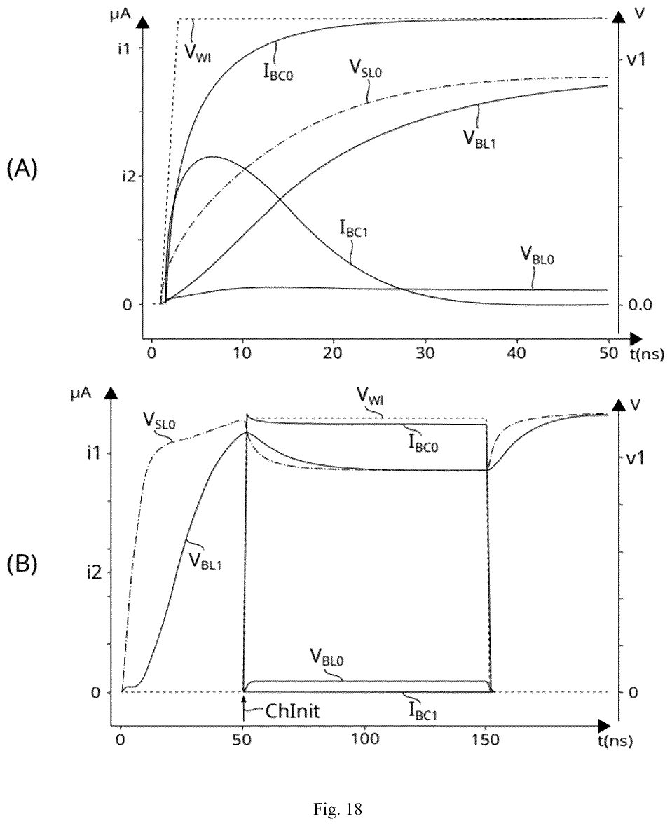

FIG. 18 represents two chronograms of currents and voltages involved in the reset operation of bit cell BC0 of FIG. 10: at (A), with a conventional sequencing for driving the memory, in which the source line SL0 and the word line WL are charged simultaneously, and at (B) with a sequencing in which the common source line SL0 of the two bit cells BC0 and BC1 and of the bit line BL1 of the non-selected bit cell BC1 are charged in anticipation compared to the word line WL. The scales of the two chronograms (A) and (B) are the same, as indicated by the current value i1 and the voltage value v1 indicated of the relevant scales.

The curves indicated as V_{WL}, V_{SL0}, V_{BL0}, and V_{BL1} show, respectively, the voltages of the word line WL, the source line SL0, the bit line BL0, and the bit line BL1, in volts, as indicated by the right-hand scale, during a reset operation applied to bit cell BC0. The curves indicated as I_{BC0} and I_{BC1} show, respectively, the intensity of current running through the bit cells BC0 and BC1, in amperes, as indicated by the left-hand scale, during the reset operation applied to bit cell BC0.

The chronogram at (A) shows that when the word line WL is charged, the voltage V_{BL1} follows the evolution of the voltage V_{SL0}. Also, the disturb transient current I_{Tr} represented by I_{BC1} attains a peak greater than a value i2 before returning close to 0 μA.

On the other hand, the chronogram at (B) illustrates the evolutions of voltages and currents when the charging of SL0 and BL1 (at timing “0 ns”) are applied 50 ns prior to initiating (at timing “50 ns” as indicated by the arrow “ChInit”) the charging of the word line WL. We can see that the transient current I_{BC1} stays close to 0 μA for the whole reset operation. This is explained by the fact that the gap in voltage between V_{SL0} and V_{BL1} is close to zero when the WL is open, thanks to the anticipated charging of the two lines SL0 and BL1.

The charging of lines SL0 and BL1 can be controlled by the multiplexer SL/BL-Mux, and Variant 3 detailed above is totally compatible and can be advantageously combined with Variant 1 and Variant 2 of this second embodiment, and with Variant 1 and Variant 2 of the first embodiment. In fact, in (A) and (B), the bit line BL1 is connected to the source line SL0 so that the transient current I_{Tr} is reduced: the present examples of FIG. 18 illustrates a situation combining either one Variant 1 and Variant 2 of reset disturb current reduction with Variant 3. If only Variant 3 was employed, the current I_{BC1} of FIG. 18(A) would be much higher.

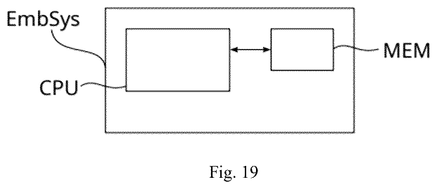

FIG. 19 illustrates an embedded system EmbSys integrating the resistive RAM in communication with a microprocessor CPU. Such a system can be a portable semiconductor device configured to treat numerical data. Generally speaking, any embedded device conventionally employing a flash memory may employ a resistive memory instead.

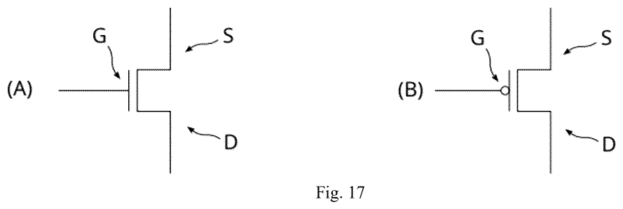

The figures of the present document use the conventional circuit symbols for transistors. For clarity, FIG. 17(A) and FIG. 17(B) illustrate respectively an n-type transistor and a p-type transistor, with their respective three connections: source S, drain D and gate G. The source and the drain are conventionally defined as follows: excluding the gate, for an n-type transistor, the source and the drain are the two connections that have, respectively, the lowest potential and the highest potential; conversely, for a p-type transistor, the source and the drain are the two connections that have, respectively, the highest potential and the lowest potential. The figures illustrate a transistor in an on state with an “ON” label, meaning that the transistor is in a current-passing state. Conversely, the figures illustrate a transistor in an off state with an “OFF” label, meaning that the transistor is in a non-current-passing state.

In this document, the term “connection” refers to “electrical connection”, and when a transistor is said to connect the first element to the second element or to be connected between a first element and a second element, it is to be understood that one of the source and the drain of the transistor is connected to the first element and the other of the source and the drain of the transistor is connected to the second element.

The embodiments mentioned in this document can be freely combined within technical limits understood by the practitioner in the field of the invention. In particular, it is advantageous to combine one of the solutions to reduce the disturb currents in a set operation with one of the solutions to reduce the disturb current in a reset operation.

Although the present description has explicitly considered solely the situation of a source line shared by, specifically, two bit cells of a same row of bit cells, it is to be understood that the invention presented here is not limited to this specific situation, and encompasses configurations in which more than two bit cells of a same row share a common source line.

Other variations to the disclosed embodiments can be understood and effected by those skilled in the art in practicing the claimed invention, from a study of the drawings, the disclosure, and the appended claims.

What is claimed is:

1. A resistive RAM having a shared source line architecture, comprising an array of bit cells, a multiplexer circuit and a driver circuit, each of the bit cells comprising a ReRAM resistor and a selection transistor connected to the ReRAM resistor, the array including:
a first column of bit cells comprising a first bit line and one source line, each connected to the multiplexer circuit, the one source line being connected to the first bit line in each of the bit cells of the first column through the respective ReRAM resistors and selection transistors;
a second column of bit cells comprising a second bit line and the one source line, each connected to the multiplexer circuit, the one source line being connected to the second bit line in each of the bit cells of the second column through the respective ReRAM resistors and selection transistors;
a given row of bit cells comprising a word line connecting gates of the selection transistors of a given one of the bit cell of the first column and a given one of the bit cells of the second column to the driver circuit;
a first additional transistor configured to connect the first bit line to a node connected to the one source line, a gate of the first additional transistor being connected to the second bit line;
a second additional transistor configured to connect the node connected to the second bit line, a gate of the second additional transistor being connected to the first bit line; and
a third additional transistor configured to connect the node to the one source line.

2. The resistive RAM according to claim 1, the resistive RAM being configured to, during a set operation or a reset operation of the given one of the bit cells of the first column, open a current path between the one source line and the second bit line so as to bypass the given bit cell of the second column.

3. The resistive RAM according to claim 1, the resistive RAM being configured to, during a set operation or a reset operation of the given one of the bit cells of the first column, turn off the first transistor and turn on the second transistor.

4. The resistive RAM according to claim 3, the resistive RAM being configured to:
when the first transistor, the second transistor and the third transistor are n-type transistors, turn on the third transistor during a set operation of the given one of the bit cells of the first column, and turn off the third transistor during a reset operation of the given one of the bit cells of the first column; and
when the first transistor, the second transistor and the third transistor are p-type transistors, turn on the third transistor during a reset operation of the given one of the bit cells of the first column, and turn off the third transistor during a set operation of the given one of the bit cells of the first column.

5. The resistive RAM according to claim 1, wherein the array is interposed between the multiplexer circuit and each of the first additional transistor and the second additional transistor, wherein the second additional transistor constitutes a part of the current path between the one source line and the second bit line.

6. The resistive RAM according to claim 5, wherein the first additional transistor and the second additional transistor are n-type transistors, and the resistive RAM is configured to turn on the second additional transistor to thereby open the current path between the one source line and the second bit line during the set operation.

7. The resistive RAM according to claim 6, wherein a source or a drain of the first additional transistor is connected to a source or a drain of the second additional transistor at the node, the third additional transistor being an n-type transistor, the resistive RAM being configured to turn on the third additional transistor during a set operation and to turn off the third additional transistor during a reset operation.

8. The resistive RAM according to claim 5, wherein the first additional transistor and the second additional transistor are p-type transistors, and the resistive RAM is configured to turn on the second additional transistor to thereby open the current path between the one source line and the second bit line during the reset operation.

9. The resistive RAM according to claim 8, wherein a source or a drain of the first additional transistor is connected to a source or a drain of the second additional transistor at the node, the third additional transistor being a p-type transistor, the resistive RAM being configured to turn on the third additional transistor during a reset operation and to turn off the third additional transistor during a set operation.

10. The resistive RAM according to claim 1, wherein each of the first additional transistor and the second additional transistor is interposed between the array and the multiplexer circuit, wherein the second additional transistor constitutes a part of the current path between the one source line and the second bit line.

11. The resistive RAM according to claim 10, wherein the first additional transistor and the second additional transistor are n-type transistors, and the resistive RAM is configured to turn on the second additional transistor to thereby open the current path between the one source line and the second bit line during the set operation.

12. The resistive RAM according to claim 11, wherein a source or a drain of the additional first additional transistor is connected to a source or a drain of the second additional transistor at the node, the third additional transistor being an n-type transistor, the resistive RAM being configured to turn on the third additional transistor during a set operation and to turn off the third additional transistor during a reset operation.

13. The resistive RAM according to claim 11, wherein the first additional transistor and the second additional transistor are p-type transistors, and the resistive RAM is configured to turn on the second additional transistor to thereby open the current path between the one source line and the second bit line during the reset operation.

14. The resistive RAM according to claim 13, wherein a source or a drain of the additional first additional transistor is connected to a source or a drain of the second additional transistor at a second node, the third additional transistor being a p-type transistor, the resistive RAM being configured to turn on the third additional transistor during a reset operation and to turn off the third additional transistor during a set operation.

15. The resistive RAM according to claim 1, further configured to, for the reset operation of the given one of the bit cells of the first column, charging the one source line and the second bit line of the given one of the bit cells of the second column prior to charging the word line of the given row.

16. An embedded system including the resistive RAM according to claim 1 connected to a microprocessor.
